(19) United States
(12) Patent Application Publication
(10) Pub. No.: US 2020/0198090 A1
(43) Pub. Date: Jun. 25, 2020

(54) CMP APPARATUS AND METHOD OF PERFORMING CERIA-BASED CMP PROCESS

(71) Applicant: XIA TAI XIN SEMICONDUCTOR (QING DAO) LTD., Qingdao (CN)

(72) Inventor: SUN-WUNG LEE, Singapore (SG)

(21) Appl. No.: 16/692,721

(22) Filed: Nov. 22, 2019

Related U.S. Application Data
(60) Provisional application No. 62/778,909, filed on Dec. 13, 2018.

(51) Int. Cl. B24B 37/015; B24B 53/017; B24B 37/04; C09G 1/02; C09K 3/14; B24B 57/02; H01L 21/321; H01L 21/3105

(52) U.S. Cl. CPC B24B 37/015; B24B 53/017; B24B 37/042; C09G 1/02; H01L 21/31053; B24B 57/02; C09K 3/1409; H01L 21/3212; C09K 3/1463

(57) ABSTRACT

The present disclosure is directed to a method of performing a ceria-based CMP process. In a first action, a slurry containing ceria particles is provided onto a polishing pad. In a second action, an oxide layer of a wafer is polished on the polishing pad by the slurry. In a third action, a cooling water having a temperature within a range of 0° C. to 5° C. is provided onto the polishing pad. In a fourth action, the wafer is polished on the polishing pad by the cooling water to remove the ceria particles from the oxide layer of the wafer.

### CROSS-REFERENCE TO RELATED APPLICATION

This application claims the benefit of and priority to a U.S. Provisional Application No. 62/778,909 filed on Dec. 13, 2018, the entire content of which is incorporated by reference herein.

### FIELD

The present disclosure generally relates to a method of performing a ceria-based chemical mechanical polishing (CMP) process and a CMP apparatus thereof. More specifically, the present disclosure relates to a method of performing a ceria-based CMP process that provides cooling water to reduce the binding force between ceria particles and a surface of a wafer after the CMP process.

### BACKGROUND

Chemical mechanical polishing or chemical mechanical planarization (CMP) is accomplished by holding the semiconductor wafer against a rotating polishing surface, or otherwise moving the wafer relative to the polishing surface, under controlled conditions of temperature, pressure, and chemical composition. The polishing surface, which may be a planar pad formed of a relatively soft and porous material such as a blown polyurethane, wetted by a chemically reactive and abrasive aqueous slurry. The aqueous slurry, which may be either acidic or basic, typically includes abrasive particles, reactive chemical agents such as transition metal chelated salts or oxidizers, and adjuvants such as solvents, buffers, and passivating agents. In the slurry, the salts or other agents provide the chemical etching action, whereas the abrasive particles, in cooperation with the polishing pad, provide the mechanical polishing action.

FIG. 1 shows an example schematic diagram of a CMP apparatus. The CMP apparatus 100 includes a carrier head 120 for holding a semiconductor wafer W. A membrane 130 is positioned between the carrier head 120 and the wafer W, with the wafer W being held against the membrane 130 by a partial vacuum or with an adhesive. The carrier head 120 is provided to be continuously rotated by a drive motor 140, in the direction 141, and optionally be reciprocated transversely in the directions 142. Accordingly, the combined rotational and transverse movements of the wafer W are intended to reduce the variability in the material removal rate across the surface of the wafer W. The CMP apparatus 100 further includes a platen 110, which is rotated in the direction 112. A polishing pad 111 is mounted on the platen 110. A slurry supply tube 151 is mounted above the platen 110 to deliver a stream of polishing slurry 153, which is dripped onto the surface of the polishing pad 111 from a nozzle 152 of the supply tube 151. If the particles in the slurry 153 form agglomeration of undesirable large particles, the wafer surface would be scratched when the wafer W is being polished. Therefore, the slurry 153 needs to be filtered to remove the undesirable large particles. Usually, a filter assembly 154 is coupled to the slurry supply tube 151 to separate agglomerated or oversized particles.

Generally, a slurry including either a silica (SiO₂)-based abrasive or a ceria(CeO₂)-based abrasive has been used in the CMP process for oxide layers on the wafer. For polishing a silicon dioxide (SiO₂) layer of a wafer, a ceria-based CMP is usually adapted due to its good hardness, higher polishing rate and its distinct oxidative ability. However, the adhesive force of CeO₂ particles to the SiO₂ surface is strong. It is difficult to break the adhesive force between CeO₂ particles and SiO₂ surface by an In Situ process. After the CMP process, an additional cleaning process by a highly acidic chemical in a separate wet clean chamber is required to remove the residual CeO₂ particles on the SiO₂ surface. The additional cleaning process raises diverse issues including cost and the increasing in amount of waste water treatment.

Accordingly, there remains a need to provide a method of performing a ceria-based CMP process to overcome the aforementioned problems.

### SUMMARY

In view of above, the present disclosure is directed to a method of performing a ceria-based chemical mechanical polishing (CMP) process and a CMP apparatus thereof to reduce the manufacture cost for semiconductor wafers.

An implementation of the present disclosure is directed to a method of performing a ceria-based CMP process. The method includes actions S401 to S404 as shown in FIG. 4. In action S401, a slurry containing ceria particles is provided onto a polishing pad. In action S402, an oxide layer of a wafer is polished on the polishing pad by the slurry. In action S403, a cooling water having a temperature within a range of 0° C. to 5° C. is provided onto the polishing pad. In action S404, the wafer is polished on the polishing pad by the cooling water to remove the ceria particles from the oxide layer of the wafer.

Another implementation of the present disclosure is directed to a CMP apparatus. The CMP apparatus includes a platen, a carrier head, a slurry supply module, and a cooling water supply module. The platen has a polishing pad for polishing a wafer by a slurry containing ceria particles. The carrier head is configured to hold the wafer. The slurry supply module is configured to supply the slurry onto the polishing pad of the platen. The cooling water supply module is configured to supply cooling water having a temperature within a range of 0° C. to 5° C. onto the polishing pad of the platen.

As described above, the method of performing a ceria-based CMP process and the CMP apparatus of the implementations of the present disclosure provide cooling water to cool the temperature of the wafer and the polishing pad after the CMP process. The cooling water reduce the binding force between ceria particles and the oxide layer on the wafer. Therefore, the residual ceria particles can be easily removed by polishing the wafer on the polishing pad without additional wet cleaning processes. The method and the CMP apparatus of the present disclosure can reduce the cost for the manufacturing of the wafer.

### BRIEF DESCRIPTION OF THE DRAWINGS

Implementations of the present technology will now be described, by way of example only, with reference to the attached figures.

FIG. 1 is a schematic diagram of a chemical mechanical polishing (CMP) apparatus according to related art.

FIG. 2A is a schematic diagram of an example CMP apparatus according to an implementation of the present disclosure; FIG. 2B is an enlarged schematic diagram showing a wafer and a polishing pad of the CMP apparatus in FIG. 2A.

FIG. 3 is a diagram showing a removal rate of a silicon dioxide (SiO₂) layer by a ceria-based slurry.

FIG. 4 is a flowchart of an example method of performing a ceria-based CMP process according to another implementation of the present disclosure.

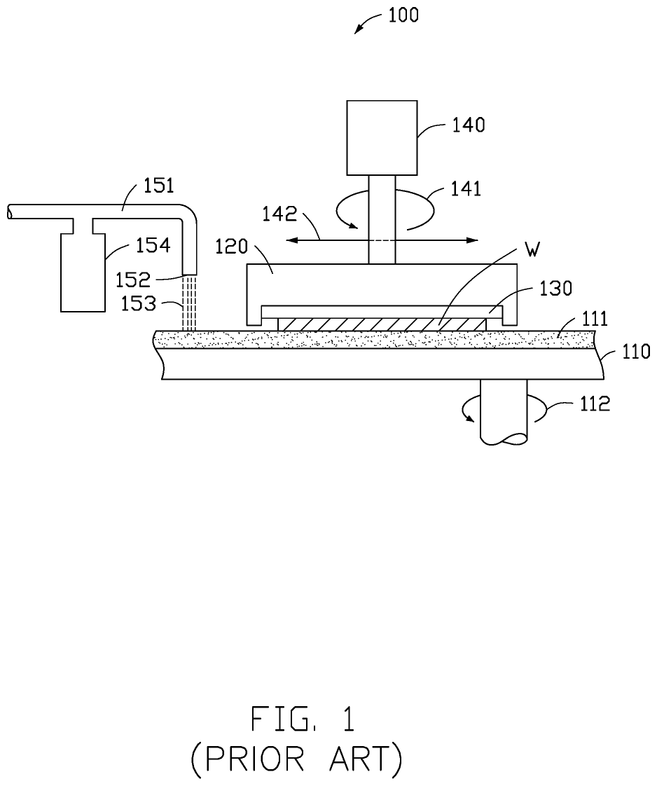

### DETAILED DESCRIPTION

The present disclosure will now be described more fully hereinafter with reference to the accompanying drawings, in which example implementations of the disclosure are shown. This disclosure may, however, be implemented in many different forms and should not be construed as limited to the example implementations set forth herein. Rather, these example implementations are provided so that this disclosure will be thorough and complete, and will fully convey the scope of the disclosure to those skilled in the art. Like reference numerals refer to like elements throughout.

The terminology used herein is for the purpose of describing particular example implementations only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, actions, operations, elements, and/or components, but do not preclude the presence or addition of one or more other features, regions, integers, actions, operations, elements, components, and/or groups thereof.

It will be understood that the term “and/or” includes any and all combinations of one or more of the associated listed items. It will also be understood that, although the terms first, second, third etc. may be used herein to describe various elements, components, regions, parts and/or sections, these elements, components, regions, parts and/or sections should not be limited by these terms. These terms are only used to distinguish one element, component, region, part or section from another element, component, region, layer or section. Thus, a first element, component, region, part or section discussed below could be termed a second element, component, region, layer or section without departing from the teachings of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

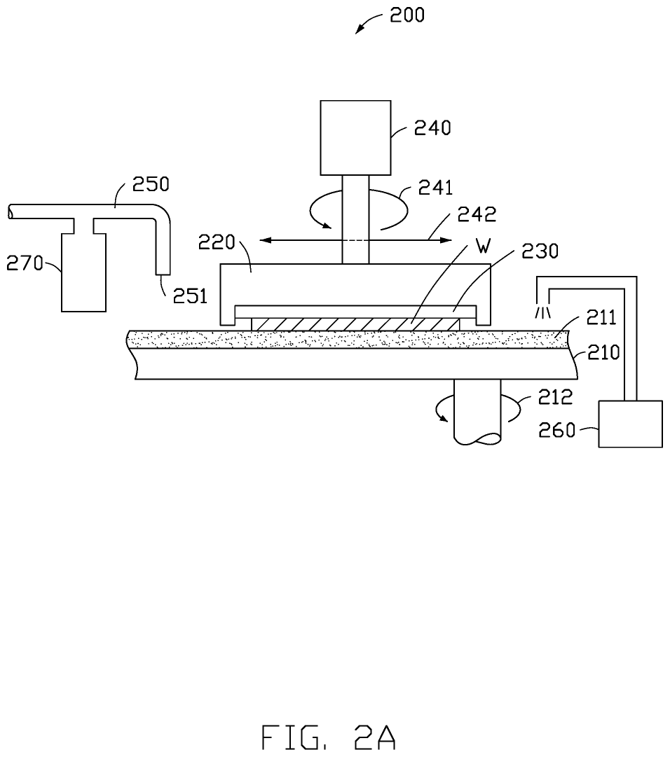

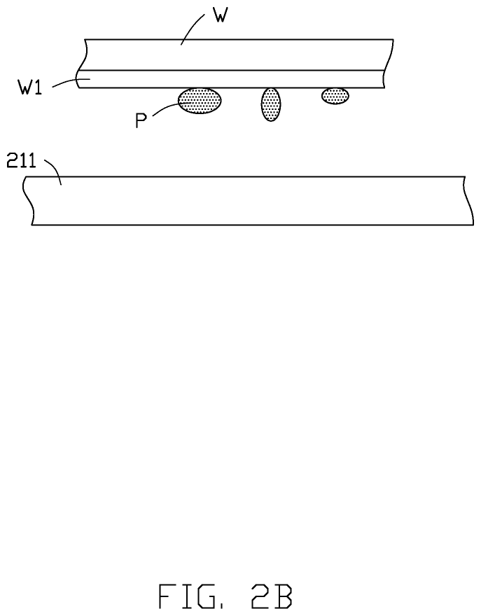

The description will be made as to the example implementations of the present disclosure in conjunction with the accompanying drawings in FIGS. 2A to 4. Reference will be made to the drawing figures to describe the present disclosure in detail, wherein depicted elements are not necessarily shown to scale and wherein like or similar elements are designated by same or similar reference numeral through the several views and same or similar terminology.

The present disclosure will be further described hereafter in combination with the accompanying figures.

Referring to FIG. 2A, a schematic diagram of a chemical mechanical polishing (CMP) apparatus 200 according to an implementation of the present disclosure is illustrated. The CMP apparatus 200 is configured to perform a CMP process for a wafer W. As shown in FIG. 2A, the CMP apparatus 200 includes a platen 210, a carrier head 220, a slurry supply module 250, and a cooling water supply module 260. The platen 210 includes a polishing pad 211 mounted on the platen 210. The polishing pad 211 of the platen 210 is configured to polish a wafer W by a slurry. The platen 210 may be rotated in a direction 212 to polish the wafer. The wafer W may include an oxide layer (such as a silicon dioxide (SiO₂) layer). When polishing the oxide layer of the wafer W, a ceria-based slurry may be used. In other words, the slurry contain ceria particles is configured to polish the oxide layer (such as SiO₂ layer) of the wafer W. The carrier head 220 is configured to hold the wafer W. The CMP apparatus 200 may further includes a drive motor 240 connected to the carrier head 220 and configured to rotate the carrier head 220. The carrier head 220 is provided to be continuously rotated by the drive motor 240, in a direction 214, and optionally be reciprocated transversely in a direction 242. Accordingly, the combined rotational and transverse movements of the wafer W are intended to reduce the variability in the material removal rate across a surface of the wafer W. As compared to the wafer W, the platen 210 is provided with a relatively large surface area to accommodate the translational movement of the wafer W on the carrier head 220 across the surface of the polishing pad 211 of the platen 210. The CMP apparatus 200 may further include a membrane 230 disposed between the carrier head 220 and the wafer W, with the wafer W being held against the membrane 230 by a partial vacuum or with an adhesive.

The slurry supply module 250 is configured to supply the slurry containing the ceria particles onto the polishing pad 211 of the platen 210 when polishing the oxide layer of the wafer W. The slurry supply module 250 is mounted above the platen 210 to deliver a stream of the slurry, which is dripped onto the surface of the polishing pad 211 from a nozzle 251 of the slurry supply module 250. The slurry may be gravity fed from a tank or reservoir (not shown), or otherwise pumped through the slurry supply module 250. Alternatively, the slurry may be supplied from below the platen 210 such that it flows upwardly through an underside of the polishing pad 211. In another implementation, the slurry may be supplied in the carrier head 220 by nozzles disposed in the carrier head 220. The ceria particles in the slurry may form agglomeration of undesirable large particles, the surface of the wafer W would be scratched when the wafer W is being polished. The slurry needs to be filtered to remove the undesirable large particles. The CMP apparatus 200 may further includes a filter assembly 270 coupled to the slurry supply module and configured to filter the slurry.

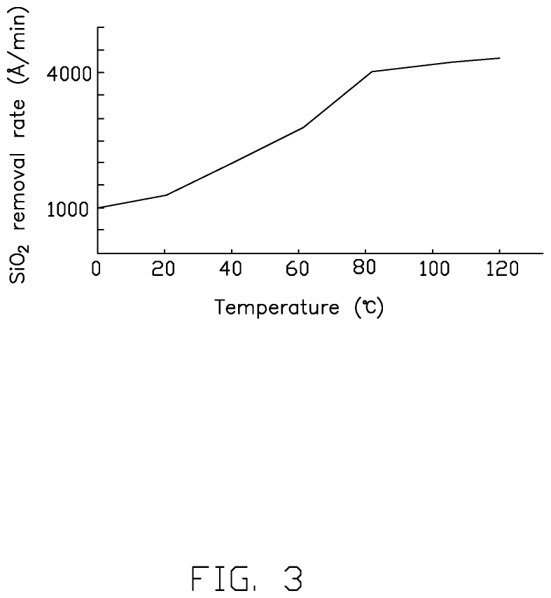

The cooling water supply module 260 is configured to supply cooling water onto the polishing pad 211 of the platen 210. The cooling water may be deionized water having a temperature within a range of 0° C. to 5° C. The oxide layer (such as SiO₂ layer) of the wafer W may be polished on the polishing pad 211 by the slurry containing the ceria particles at a room temperature. The ceria particles have strong binding force with the SiO₂ layer. The strong binding force between ceria and SiO₂ allows a high removal rate when using ceria-based slurry to perform the CMP process for the SiO₂ layer on the wafer W. For example, as shown in FIG. 3, the removal rate of SiO₂ is higher than 1500 Å/min by using ceria-based slurry at a room temperature. The CMP process for the SiO₂ layer with ceria-based slurry may be also performed at a temperature higher than the room temperature, which results in a higher removal rate of the SiO₂ layer, as shown in FIG. 3. However, after the CMP process is completed, such binding force become problematic as the residual ceria particles in the slurry are likely to attached on the surface of the SiO₂ layer. Particularly, the temperature on the surface of the wafer W may be elevated due to the friction force between the wafer W and the polishing pad 211, and the binding force between the ceria particles and the SiO₂ layer is increased. As shown in FIG. 2B, the surface of the SiO₂ layer (indicated as W1) of the wafer W is attached with the residual ceria particles (indicated as P) in the slurry after the CMP process. The ceria particles on the SiO₂ layer cannot be removed by a post-CMP double side scrubber which cleans the wafer with PVA brushes. A wet cleaning process using cleaning agents is usually required to remove the ceria particles on the SiO₂ layer.

The cooling water supply module 260 is configured to supply cooling water onto the polishing pad 211 of the platen 210. The cooling water may be deionized water having a temperature within a range of 0° C. to 5° C. When the polishing of the SiO₂ layer of the wafer W is completed, the slurry supply module 250 stops supplying the slurry onto the polishing pad 211 of the platen 210, and the cooling water supply module 260 supplies the cooling water onto the polishing pad 211 of the platen 210 to cool the wafer W and the polishing pad 211 of the platen 210. The wafer W and the polishing pad 211 of the platen 210 is cooled to a temperature within a range of 0° C. to 20° C., preferably 0° C. to 15° C., and more preferably 0° C. to 5° C. After the cooling water is supplied onto the polishing pad 211 of the platen 210, the ceria particles on the SiO₂ layer of the wafer W are removed by polishing the wafer W on the polishing pad by the cooling water. Specifically, the cooling water cools the temperature of the wafer and the polishing pad below 20° C., the binding force between the ceria particles and the SiO₂ layer of the wafer W is greatly reduced at the temperature below 20° C., as shown in FIG. 3 (a reduced removal rate indicates a reduced binding force). Therefore, the ceria particles can be removed by polishing the wafer W on the polishing pad 211 while continuously supplying the cooling water onto the polishing pad 211. When polishing the wafer W on a polishing pad 221 by the cooling water, the carrier head holds the wafer W to rotate in the direction 214, and optionally be reciprocated transversely in the directions 242, and the platen rotates in the direction 212. The ceria particles are then removed by the friction force between the wafer W and the polishing pad. Accordingly, no wet cleaning process is required to remove the residual ceria particles on the surface of the wafer W.

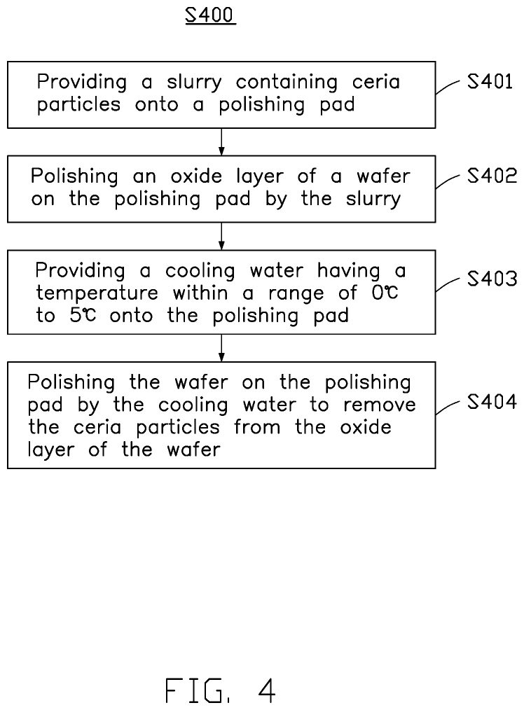

Referring to FIG. 4, a flowchart of a method S400 of performing a ceria-based chemical mechanical polishing (CMP) process according to another implementation of the present disclosure is illustrated. As shown in FIG. 4, the method S400 includes action S401 to S404. The method S400 is carried out by the CMP apparatus of FIGS. 2A and 2B. The CMP apparatus 200 includes a platen 210, a carrier head 220, a slurry supply module 250, and a cooling water supply module 260. The platen 210 includes a polishing pad 211 mounted on the platen 210. In action S401, a slurry containing ceria particles is provided on to the polishing pad 211 of the platen 210. The slurry is dripped onto the surface of the polishing pad 211 from a nozzle 251 of the slurry supply module 250. The slurry may be gravity fed from a tank or reservoir (not shown), or otherwise pumped through the slurry supply module 250. Alternatively, the slurry may be supplied from below the platen 210 such that it flows upwardly through an underside of the polishing pad 211. In another implementation, the slurry may be supplied in the carrier head 220 by nozzles disposed in the carrier head 220.

In action S402, an oxide layer of a wafer W is polished on the polishing pad 211 of the platen 210 by the slurry. The wafer W is loaded to the carrier head 220. When polishing the oxide layer of the wafer W, the carrier head 220 holds the wafer W and is continuously rotated by a drive motor 240 of the CMP apparatus 200, in a direction 214, and optionally be reciprocated transversely in a direction 242. The combined rotational and transverse movements of the wafer W are intended to reduce the variability in the material removal rate across a surface of the wafer W. As compared to the wafer W, the platen 210 is provided with a relatively large surface area to accommodate the translational movement of the wafer W on the carrier head 220 across the surface of the polishing pad 211 of the platen 210. The platen 210 may also rotate in a direction 212. The oxide layer of the wafer W may be a SiO₂ layer. The ceria particles have strong binding force with the SiO₂ layer. The strong binding force between ceria and SiO₂ allows a high removal rate when using ceria-based slurry to perform the CMP process for the SiO₂ layer of the wafer W. The SiO₂ layer of the wafer may be polished on the polishing pad by the slurry at a room temperature. As shown in FIG. 3, the removal rate of SiO₂ is higher than 1500 Å/min by using ceria-based slurry at the room temperature. The CMP process for the SiO₂ layer with ceria-based slurry may be also performed at a temperature higher than the room temperature, which results in a higher removal rate of the SiO₂ layer, as shown in FIG. 3.

After the oxide layer of the wafer is polished (i.e., the slurry supply module 250 stops providing slurry onto the polishing pad 211), in action S403, a cooling water having a temperature within a range of 0° C. to 5° C. is provided onto the polishing pad 211 of the platen 210. The cooling water is provided by the cooling water supply module 260. After the polishing process for the oxide layer of the wafer is completed, the residual ceria particles in the slurry are likely to attached on the surface of the SiO₂ layer due to the strong binding force between ceria particles and SiO₂. Particularly, the temperature on the surface of the wafer W may be elevated due to the friction force between the wafer W and the polishing pad 211, and the binding force between the ceria particles and the SiO₂ layer is increased, as shown in FIG. 3. The cooling water is provided to cool the wafer W and the polishing pad 211 to a temperature within a range of 0° C. to 20° C., preferably 0° C. to 15° C., and more preferably 0° C. to 5° C. The binding force between the ceria particles and the SiO₂ layer of the wafer W is greatly reduced at the temperature below 20° C., as shown in FIG. 3 (a reduced removal rate indicates a reduced binding force).

In action S404, the wafer W is polished on the polishing pad 211 by the cooling water to remove the ceria particles from the surface of the oxide layer of the wafer. Since the binding force between the ceria particles and the SiO₂ layer of the wafer W is greatly reduced by providing cooling water onto the polishing pad 211, the ceria particles on the surface of the oxide layer can be easily removed by polishing the wafer W on the polishing pad 211 while continuously supplying the cooling water onto the polishing pad 211. When polishing the wafer by the cooling water, the carrier head 220 holds the wafer W and is continuously rotated by the drive motor 240, in the direction 214, and optionally be reciprocated transversely in the direction 242. The platen 210 may also rotate in the direction 212. Also, in action S404, most of the residual slurry on the surface of the wafer W is washed away by the cooling water.

As described above, the method of performing a ceria-based CMP process and the CMP apparatus of the implementations of the present disclosure provides cooling water to cool the temperature of the wafer and the polishing pad after the CMP process. The cooling water reduce the binding force between ceria particles and the oxide layer on the wafer. Therefore, the residual ceria particles can be easily removed by polishing the wafer on the polishing pad without additional wet cleaning processes. The method and the CMP apparatus of the present disclosure can reduce the cost for the manufacturing of the wafer.

The implementations shown and described above are only examples. Many details are often found in the art such as the other features of a method of performing a ceria-based CMP process and a CMP apparatus thereof. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the implementations described above may be modified within the scope of the claims.

What is claimed is:

1. A method of performing a ceria-based chemical mechanical polishing (CMP) process, comprising actions of:
providing a slurry containing ceria particles onto a polishing pad;
polishing an oxide layer of a wafer on the polishing pad by the slurry;
providing a cooling water having a temperature within a range of 0° C. to 5° C. onto the polishing pad; and
polishing the wafer on the polishing pad by the cooling water to remove the ceria particles from the oxide layer of the wafer.

2. The method of claim 1, wherein the oxide layer of the wafer is a silicon oxide layer.

3. The method of claim 1, wherein the cooling water is provided to cool the wafer and the polishing pad to a temperature within a range of 0° C. to 20° C.

4. The method of claim 3, wherein the wafer and the polishing pad is cooled to a temperature within a range of 0° C. to 15° C.

5. The method of claim 4, wherein the wafer and the polishing pad is cooled to a temperature within a range of 0° C. to 5° C.

6. The method of claim 1, wherein the oxide layer of the wafer is polished on the polishing pad by the slurry at a room temperature.

7. A chemical mechanical polishing (CMP) apparatus, comprising:
a platen having a polishing pad for polishing a wafer by a slurry containing ceria particles;
a carrier head configured to hold the wafer;
a slurry supply module configured to supply the slurry onto the polishing pad of the platen; and
a cooling water supply module configured to supply cooling water having a temperature within a range of 0° C. to 5° C. onto the polishing pad of the platen.

8. The CMP apparatus of claim 7, wherein the wafer comprises an oxide layer, the slurry is configured to polish the oxide layer of the wafer.

9. The CMP apparatus of claim 8, wherein the oxide layer of the wafer is polished by the slurry at a room temperature.

10. The CMP apparatus of claim 8, wherein when the polishing of the oxide layer of the wafer is completed, the slurry supply module stops supplying the slurry onto the polishing pad of the platen, and the cooling water supply module supplies the cooling water onto the polishing pad of the platen to cool the wafer and the polishing pad of the platen.

11. The CMP apparatus of claim 10, wherein after the cooling wafer is supplied onto the polishing pad of the platen, the ceria particles on the oxide layer of the wafer are removed by polishing the wafer on the polishing pad by the cooling water.

12. The CMP apparatus of claim 10, wherein the wafer and the polishing pad of the platen is cooled to a temperature within a range of 0° C. to 20° C.

13. The CMP apparatus of claim 12, wherein the wafer and the polishing pad is cooled to a temperature within a range of 0° C. to 15° C.

14. The CMP apparatus of claim 13, wherein the wafer and the polishing pad is cooled to a temperature within a range of 0° C. to 5° C.

15. The CMP apparatus of claim 7, further comprising a drive motor connected to the carrier head and configured to rotate the carrier head.

16. The CMP apparatus of claim 7, further comprising a filter assembly coupled to the slurry supply module and configured to filter the slurry.
